(19) United States
(12) Patent Application Publication
(10) Pub. No.: US 2024/0081155 A1
(43) Pub. Date: Mar. 7, 2024

(54) MAGNETIC TUNNEL JUNCTION STRUCTURE WITH NON-MAGNETIC AMORPHOUS INSERTION LAYER

(71) Applicant: HeFeChip Corporation Limited, Sai Ying Pun (HK)

(72) Inventors: Young-suk Choi, Niskayuna, NY (US); Qinli Ma, Mt Kisco, NY (US); Wei-Chuan Chen, Scarsdale, NY (US)

(73) Assignee: HeFeChip Corporation Limited, Sai Ying Pun (HK)

(21) Appl. No.: 17/938,967

(22) Filed: Sep. 7, 2022

(51) Int. Cl. H01L 43/02; H01F 10/32; H01L 27/22; H01L 43/10

(52) U.S. Cl. CPC H01L 43/02; H01F 10/3254; H01L 27/222; H01L 43/10

(57) ABSTRACT

A semiconductor memory device includes a bottom electrode, a magnetic tunnel junction (MTJ) structure disposed over the bottom electrode, a seed layer disposed between the MTJ structure and the bottom electrode, and a non-magnetic amorphous insertion layer disposed between the seed layer and the bottom electrode.

### BACKGROUND OF THE INVENTION

### 1. Field of the Invention

The invention relates to a magnetic memory device, and more particularly, to an improved magnetic tunnel junction (MTJ) structure in a magnetoresistive random access memory (MRAM) cell.

### 2. Description of the Prior Art

Magnetoresistive random access memory (MRAM), based on the integration of silicon CMOS with MTJ technology, is a major emerging technology that is highly competitive with existing semiconductor memories such as SRAM, DRAM, Flash, etc. A MRAM device is generally comprised of an array of parallel first conductive lines such as word lines on a horizontal plane, an array of parallel second conductive lines such as bit lines on a second horizontal plane spaced above and formed in a direction perpendicular to the first conductive lines, and a MTJ element interposed between a first conductive line and a second conductive line at each crossover location. Typically, access transistors may be disposed below the array of first conductive lines to select certain MRAM cells within the MRAM array for read or write operations.

A MTJ element is based on tunnel magneto-resistance (TMR) effect wherein a stack of layers has a configuration in which two ferromagnetic layers are separated by a thin non-magnetic dielectric layer or tunnel barrier layer. If the tunnel barrier layer is thin enough (typically a few angstroms to a few nanometers), electrons can tunnel from one ferromagnet into the other. In a MRAM device, the MTJ element is typically formed between a bottom electrode and a top electrode. A MTJ stack of layers that is subsequently patterned to form a MTJ element may be formed by sequentially depositing a seed layer, a reference layer formed by two reference-pinned layers antiferromagnetically coupled with each other and a polarization-enhancement layer (PEL) between one reference-pinned layer and the tunnel barrier layer, a thin tunnel barrier layer, a ferromagnetic “free” layer or storage layer, and a capping layer.

It is desirable to provide an improved MTJ structure in a magnetic memory device, which is able to provide high perpendicular magnetic anisotropy (PMA), low damping, higher spin transfer torque (STT) efficiency, smaller distribution of coercivity (Hc) and/or critical voltage (Vc), and high TMR ratio.

### SUMMARY OF THE INVENTION

It is one object to provide an improved MTJ structure to solve the shortcomings or disadvantages of the above-mentioned prior art.

One aspect of the invention provides a semiconductor memory device including a bottom electrode, a magnetic tunnel junction (MTJ) structure disposed over the bottom electrode, a seed layer disposed between the MTJ structure and the bottom electrode, and a non-magnetic amorphous insertion layer disposed between the seed layer and the bottom electrode.

According to some embodiments, the seed layer comprises Pt, Co, Ir, Ru or a combination thereof.

According to some embodiments, the non-magnetic amorphous insertion layer comprises a bottom layer directly disposed on the bottom electrode, a middle layer directly disposed on the bottom layer, and a top layer directly disposed on the middle layer, wherein the bottom layer, the middle layer, and the top layer have different compositions.

According to some embodiments, the bottom layer is an amorphous magnetic film, the middle layer is a non-magnetic conductive film, and the top layer is a non-magnetic metal film.

According to some embodiments, the non-magnetic amorphous insertion layer can form a multiple repeats of the tri-layer structure as a structure of [bottom layer/middle layer/top layer]n, where n is a number of repeats.

According to some embodiments, the amorphous magnetic film comprises (CoₓFe₁₀₀₋ₓ)_{y}B_{100-y}, wherein 0≤x≤100 and 20≤y≤80.

According to some embodiments, the amorphous magnetic film has a thickness of 2-10 angstroms.

According to some embodiments, the amorphous magnetic film comprises CoFeB, TbFe, TbCo, GdCo, or CoFeSi, CoFeBTa, CoFeBW, CoFeBMo, CoSiBZr, CoFeBTi, CoFeBHc, CoFeBNb.

According to some embodiments, the non-magnetic conductive layer comprises MgO, LaNiOx, TiOx, MgZnOx, TaN, or TiN.

According to some embodiments, the non-magnetic conductive layer has a thickness of 0.1-5 angstroms.

According to some embodiments, the non-magnetic metal film comprises Ta, W, Mo, Zr, Ti, Hf, Nb, or a combination thereof.

According to some embodiments, the non-magnetic metal film has a thickness of 0.1-10 angstroms.

According to some embodiments, the bottom layer is a non-magnetic metal film, the middle layer is a non-magnetic conductive film, and the top layer is an amorphous magnetic film.

According to some embodiments, the non-magnetic metal film comprises Ta, W, Mo, Zr, Ti, Hf, Nb, or a combination thereof.

According to some embodiments, the non-magnetic conductive layer comprises MgO, LaNiOx, TiOx, MgZnOx, TaN, or TiN.

According to some embodiments, the amorphous magnetic film comprises (CoₓFe₁₀₀₋ₓ)_{y}B_{100-y}, wherein 0≤x≤100 and 20≤y≤80.

According to some embodiments, the amorphous magnetic film has a thickness of 2-10 angstroms.

According to some embodiments, the amorphous magnetic film comprises CoFeB, TbFe, TbCo, GdCo, or CoFeSi, CoFeBTa, CoFeBW, CoFeBMo, CoSiBZr, CoFeBTi, CoFeBHc, CoFeBNb.

According to some embodiments, the semiconductor memory device further comprises an insulator surrounding the bottom electrode. The non-magnetic amorphous insertion layer is in direct contact with the bottom electrode and the insulator.

According to some embodiments, the bottom electrode has a first width and the MTJ structure has a second width, wherein the second width is greater than the first width.

According to some embodiments, the insulator comprises silicon oxide.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic, cross-sectional diagram showing an exemplary MTJ structure according to an embodiment;

FIG. 2 is a schematic, cross-sectional diagram showing an exemplary MTJ structure according to another embodiment; and

FIG. 3 is a schematic, cross-sectional diagram showing an exemplary MTJ structure comprising a repeated tri-layered structure according to still another embodiment.

### DETAILED DESCRIPTION

Advantages and features of embodiments may be understood more readily by reference to the following detailed description of preferred embodiments and the accompanying drawings. Embodiments may, however, be embodied in many different forms and should not be construed as being limited to those set forth herein. Rather, these embodiments are provided so that this disclosure will be thorough and complete and will fully convey exemplary implementations of embodiments to those skilled in the art, so embodiments will only be defined by the appended claims. Like reference numerals refer to like elements throughout the specification.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

A magnetic tunnel junction (MTJ) stack includes first and second ferromagnetic films separated by a barrier layer. One of the ferromagnetic films (often referred to as a “reference layer”) has a fixed magnetization direction, while the other ferromagnetic film (often referred to as a “free layer”) has a variable magnetization direction. If the magnetization directions of the reference layer and free layer are in a parallel orientation, it is more likely that electrons will tunnel through the barrier layer, such that the MTJ stack is in a low-resistance state. Conversely, if the magnetization directions of the reference layer and free layer are in an anti-parallel orientation, it is less likely that electrons will tunnel through the tunnel barrier layer, such that the MTJ stack is in a high-resistance state. Consequently, the MTJ stack can be switched between two states of electrical resistance, a first state with a low resistance (R_{P}: magnetization directions of reference layer and free layer are parallel) and a second state with a high resistance (R_{AP}: magnetization directions of reference layer and free layer are anti-parallel). Because of this binary nature, MTJ stacks are used in memory cells to store digital data, with the low resistance state R_{P} corresponding to a first data state (e.g., logical “0”), and the high-resistance state R_{AP} corresponding to a second data state (e.g., logical “1”).

An MTJ stack is typically disposed between a bottom electrode and a top electrode, and the reference layer, free layer, and barrier layer are manufactured to have a face-centered-cubic (fcc) structure with (111) orientation. Typically, the MTJ stack is grown from a seed layer to form the MTJ stack with this structure and orientation. However, growing MTJ stacks from conventional seed layers may result in imperfections in the MTJ stacks. For example, conventional MTJ stacks can exhibit a significant number of grain boundaries per unit area, and these grain boundaries make the MTJ stack susceptible to diffusive species, such as tantalum or ruthenium from the bottom electrode, diffusing into the MTJ stack from the bottom electrode. These grain boundaries can also degrade the quality of the fcc structure and (111) orientation for the MTJ stack, which can impair operating characteristics of the MTJ stack, especially over thermal stress and aging. To obtain the correct crystallographic orientation and good texture quality, a careful seed selection is required.

The present disclosure pertains to a semiconductor memory device, and more specifically, a magnetoresistive random access memory (MRAM) cell having an improved MTJ structure with a non-magnetic amorphous insertion layer disposed between the metal contact and the seed layer. The non-magnetic amorphous insertion layer has a multi-film structure.

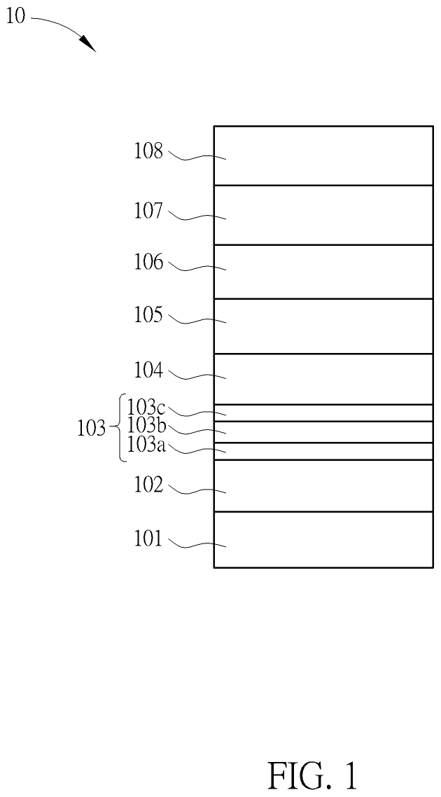

FIG. 1 is a schematic, cross-sectional diagram showing an exemplary magnetic tunnel junction (MTJ) structure according to an embodiment. As shown in FIG. 1, the MTJ structure 10 is sandwiched between a bottom electrode (or a metal contact) 102 and a top electrode 108 such as Ru. The bottom electrode 102 may comprise a TaN or TiN via, but is not limited thereto. The MTJ structure 10 may comprise a reference layer 105 over the bottom electrode 102, a tunnel barrier layer 106 on the reference layer 105, and a storage layer (or a free layer) 107 contacting a lower surface of the top electrode 108. The tunnel barrier layer 106 is interposed between the reference layer 105 and the storage layer 107. The bottom electrode 102 may be disposed on a metal layer 101 such as a copper metal layer.

According to some embodiments, the reference layer 105 may comprise RL_PL1|AFC-spacer|RL_PL2|metal-spacer|PEL, wherein RL_PL1 and RL_PL2 are ferromagnetic layers having strong perpendicular magnetic anisotropy, which may be made of [Co/Pt]n, [Co/Pd]n, [Co/Ni]n multilayers, [Co/Ir]n and [Fe/Rh]n; FePt, CoPt, FePd, TeFeCo, GdCo, MnGa, MnGe, MnSi, alloys thereof, or any combination thereof. The RL_PL1 and RL_PL2 may have a thickness of about 10 to 50 angstroms. Metal-spacer may comprise metal having amorphous texture, which provides PMA of polarization-enhancement layer (PEL). Metal-spacer may be made of Ta, Mo, W, Ir, Rh, Zr, Nb, Hf, Cr, V, Bi or any combination thereof, having a thickness of 0.5 to 5 angstroms. PEL is ferromagnet having high spin polarization and acquiring PMA at the interface of Metal-spacer and tunnel barrier. PEL may be made of Fe, Co, Ni, Mn magnetic elements and B, Al, Si, non-magnetic elements, such as CoFeB, CoFeAl, and CoMnSi. The thickness of PEL is about 4 to 15 angstroms. AFC-spacer is metal that provides antiferromagnetic coupling between RL_PL1, RL_PL2 and PEL. AFC-spacer may comprise Ru, Ir, Rh, Cr and Re. The thickness of AFC-spacer is about 2 to 15 angstroms.

According to an exemplary embodiment, the tunnel barrier layer 106 may comprise an insulator, including but not limited to MgO. The tunnel barrier layer 106 is not limited to MgO. In some embodiments, the tunnel barrier layer 106 may comprise AlOx, TiOx, HfOx, MgAlOx, MgZnOx, TaOx, VOx, or any combination thereof. The tunnel barrier layer 106 may have a thickness of 5 to 30 angstroms.

According to an exemplary embodiment, the storage layer 107 may be a multi-layered stack having a thickness of about 1050 angstroms, for example, 20 angstroms. For example, the storage layer 107 may comprise a first ferromagnetic layer disposed directly on the tunnel barrier layer 106, a first dust layer disposed directly on the first ferromagnetic layer, a second ferromagnetic layer disposed directly on the first dust layer, a second dust layer disposed directly on the second ferromagnetic layer, a third ferromagnetic layer disposed directly on the second dust layer, and a capping oxide layer disposed directly on the third ferromagnetic layer and directly contacting a lower surface of the top electrode 108.

According to an exemplary embodiment, for example, the capping oxide layer may comprise MgO. The capping oxide layer is not limited to MgO. In some embodiments, the capping oxide layer may comprise AlOx, TiOx, HfOx, MgAlOx, MgZnOx, SiOx, TaOx and VOx, or any combination thereof. The capping oxide layer may have a thickness of 5 to 30 angstroms.

According to an exemplary embodiment, the first ferromagnetic layer, the second ferromagnetic layer, and the third ferromagnetic layer may be comprised of Fe-rich alloys or magnetic multilayer. The first ferromagnetic layer has one surface that forms an interface with the tunnel barrier layer 106 to obtain perpendicular magnetic anisotropy. The third ferromagnetic layer has one surface that forms an interface with the capping oxide layer to obtain perpendicular magnetic anisotropy.

For example, the first ferromagnetic layer, the second ferromagnetic layer, and the third ferromagnetic layer may be made of at least one of the following materials: Fe, CoFe, CoFeB, CoFeAl, CoMnSi, CoPt, FePt, CoPd, FePd, TeFeCo, GdCo, MnGa, MnGe, MnAl, MnSi or combinations thereof. The thickness of the first ferromagnetic layer may range from 5 angstroms to 20 angstroms. The thickness of the second ferromagnetic layer may range from 0 angstrom to 10 angstroms. The thickness of the third ferromagnetic layer may range from 1 angstrom to 10 angstroms.

The first dust layer is sandwiched by the first ferromagnetic layer and the second ferromagnetic layer. According to an exemplary embodiment, the first dust layer may comprise a non-magnetic metal layer, which may be made of at least one of the following materials: Ta, W, Mo, Nb, Mg, Al, C, V, Hf, Ir, Rh, Zr, Cr, Bi, and/or combinations thereof. According to an exemplary embodiment, the thickness of the first dust layer may range between 0.5 angstroms and 5 angstroms, for example, 1 angstrom. The second dust layer is sandwiched by the second ferromagnetic layer and the third ferromagnetic layer. According to an exemplary embodiment, the second dust layer may comprise a non-magnetic metal layer, which may be made of at least one of the following materials: Ta, W, Mo, Nb, Mg, Al, C, V, Hf, Ir, Rh, Zr, Cr, Bi, and/or combinations thereof. According to an exemplary embodiment, the thickness of the second dust layer may range between 0.1 angstroms and 5 angstroms, for example, 1 angstrom.

According to an exemplary embodiment, a seed layer 104 may be interposed between the bottom electrode 102 and the reference layer 105. For example, the seed layer 104 may comprise Pt, Co, Ru, Ir or a combination thereof. The seed layer 104 underneath the reference layer 105 can modulate the texture structure of the tunnel junction layers and change the interface quality between different layers of the film stacks as well. According to an exemplary embodiment, the seed layer 104 does not comprise Ni, Cr, or NiCr because the thermal stability of the amorphous-phase NiCr is not compatible with the back-end of line (BEOL) process. It is undesirable that the amorphous-phase NiCr may be crystallized during BEOL annealing processes.

According to an exemplary embodiment, to avoid the crystallinity of the bottom electrode 102 and the metal layer 101 from disturbing the texture seeding of the seed layer 104 and to block inter-diffusion in the MTJ structure, a non-magnetic amorphous insertion layer 103 is incorporated between the seed layer 104 and the bottom electrode 102. According to an exemplary embodiment, the non-magnetic amorphous insertion layer 103 comprises three consecutive layers including a bottom layer 103a directly disposed on the bottom electrode 102, a middle layer 103b directly disposed on the bottom layer 103a, and a top layer 103c directly disposed on the middle layer 103b. The bottom layer 103a, the middle layer 103b, and the top layer 103c have different compositions. According to an exemplary embodiment, the bottom layer 103a is an amorphous magnetic film, the middle layer 103b is a non-magnetic conductive film, and the top layer 103c is a non-magnetic metal film.

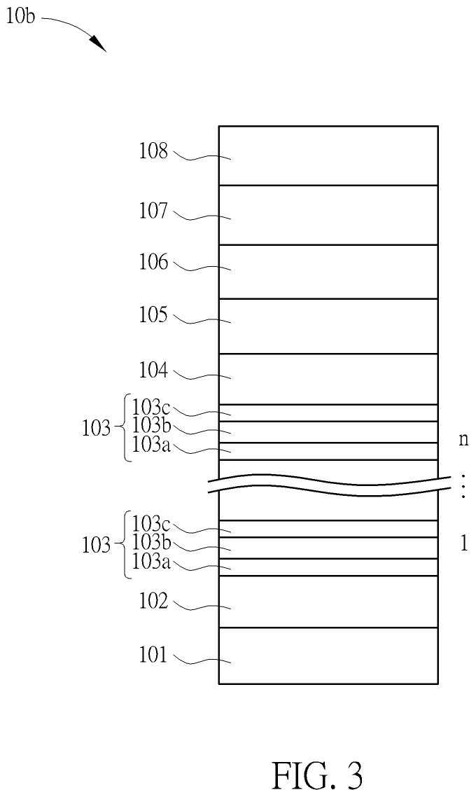

According to an exemplary embodiment, as shown in FIG. 3, the MTJ structure 10b comprises a tri-layered structure composed of the non-magnetic amorphous insertion layer 103, which can form a multiple repeats of the tri-layer in the form of [103a/103b/103c]n, where n is a number of repeats.

According to an exemplary embodiment, the amorphous magnetic film of the bottom layer 103a may have a thickness of 2-10 angstroms and a composition of (CoₓFe₁₀₀₋ₓ)_{y}B_{100-y}, wherein 0≤x≤100 and 20≤y≤80, which can provide small film stress, smooth surface, and negligible magnetic property when its thickness is less than 5 angstroms. According to some embodiments, the amorphous magnetic film of the bottom layer 103a may comprise non-stoichiometric CoFeB, TbFe, TbCo, GdCo, CoFeBTa, CoFeBW, CoFeBMo, CoSiBZr, CoFeBTi, CoFeBHc, CoFeBNb, or CoFeSi, which comprises glass-forming elements such as B, Si, Tb, or Gd, and can be deposited by physical vapor deposition (PVD) techniques. The crystallization temperatures of the amorphous magnetic film of the bottom layer 103a can be controlled by adjusting the composition and therefore no concern of thermal stability.

According to an exemplary embodiment, the non-magnetic conductive layer of the middle layer 103b may comprise conductive oxide or nitride layer including, but not limited to, non-stoichiometric MgO, LaNiOx, TiOx, MgZnOx, TaN, or TiN with thickness from 0.1-5 angstroms. Atomic inter-diffusion of boron during the subsequent annealing process may degrade the performance of the MTJs. The non-magnetic conductive oxide/nitride film may function as a diffusion barrier that prevents the inter-diffusion of the boron atoms derived from the CoFeB bottom layer 103a.

According to an exemplary embodiment, the non-magnetic metal film of the top layer 103c may comprise Ta, W, Mo, Zr, Ti, Hf, Nb, or a combination thereof, with a thickness of 0.1-10 angstroms. The high chemical affinity of non-magnetic metal layer can further prevent boron diffusion.

According to some embodiments, the bottom layer 103a may comprise non-magnetic metal film comprising Ta, W, Mo, Zr, Ti, Hf, Nb, or a combination thereof, with a thickness of 0.1-10 angstroms, and the top layer 103c may have a composition of (CoₓFe₁₀₀₋ₓ)_{y}B_{100-y}, wherein 0≤x≤100 and 20≤y≤80. According to some embodiments, the non-magnetic amorphous insertion layer 103 can have a repeating layer structure of [non-magnetic metal layer/non-magnetic conductive layer/amorphous magnetic layer]n, wherein n is an integral between 1-5, inclusive.

The non-magnetic amorphous insertion layer 103 can prevent crystallinity of the bottom electrode 102 and the metal layer 101 from disturbing the texture seeding of the seed layer 10. In addition, the non-magnetic amorphous insertion layer 103 can prevent impurity derived from the bottom electrode 102 and the metal layer 101 from inter-diffusing into the seed layer 104 after chemical mechanical polishing (CMP). The radial resistance-area products (RA)/tunnel magnetoresistance (TMR) uniformity on 300 mm wafer can be improved.

The minimum interface energy at amorphous/fcc-phase seed layer allows strong (111) texture formation of seed layer, which induces strong (111) texture of superlattice in the pinned layer. The non-magnetic amorphous insertion layer 103 uses existing materials in the MTJ, therefore, no additional target/cathode in the PVD process is required. Further, a reactive sputtering process is not required and the process stability for mass production can be improved.

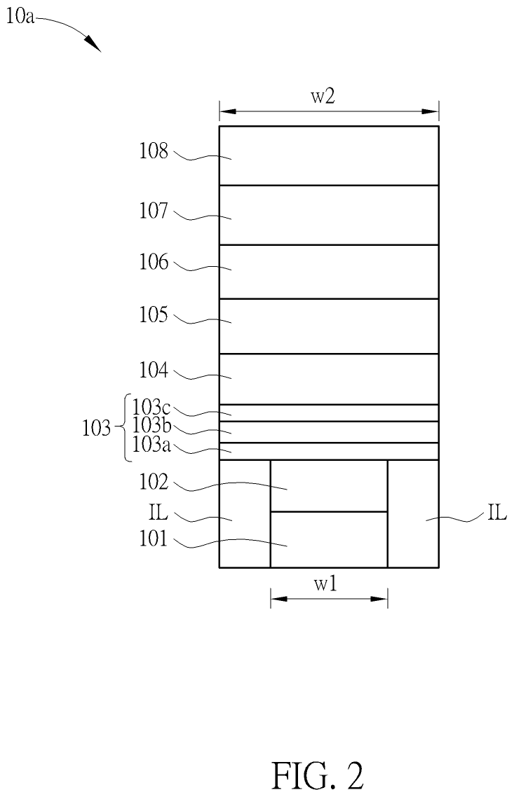

FIG. 2 is a schematic, cross-sectional diagram showing an exemplary MTJ structure according to another embodiment, wherein like regions, layers, or elements are designated by like numeral numbers or labels. As shown in FIG. 2, likewise, the MTJ structure 10a is sandwiched between a bottom electrode (or a metal contact) 102 and a top electrode 108 such as Ru. The bottom electrode 102 may comprise a TaN or TiN via, but is not limited thereto. The MTJ structure 10a may comprise a reference layer 105 over the bottom electrode 102, a tunnel barrier layer 106 on the reference layer 105, and a storage layer 107 contacting a lower surface of the top electrode 108. The tunnel barrier layer 106 is interposed between the reference layer 105 and the storage layer 107. The bottom electrode 102 may be disposed on a metal layer 101 such as a copper metal layer. A seed layer 104 is interposed between the bottom electrode 102 and the reference layer 105.

According to an exemplary embodiment, the metal layer 101 and the bottom electrode 102 may be surrounded by an insulator IL. According to an exemplary embodiment, the insulator IL may comprise silicon oxide, but is not limited thereto. According to an exemplary embodiment, the metal layer 101 and the bottom electrode 102 may have a first width w1 and the MTJ structure 10a may have a second width w2, wherein the second width w2 is greater than the first width w1. Therefore, the MTJ structure 10a protrudes beyond an edge or vertical sidewall of the metal layer 101 and the bottom electrode 102. The crystalline discontinuity between the bottom electrode 102 and the insulator IL may lead to laterally inhomogeneous texture in the MTJ structure 10a if the seed layer 104 is directly deposited on the surface of the bottom electrode 102 and the insulator IL.

According to an exemplary embodiment, to avoid the laterally inhomogeneous texture in the MTJ structure, a non-magnetic amorphous insertion layer 103 is incorporated between the seed layer 104 and the bottom electrode 102. The non-magnetic amorphous insertion layer 103 is in direct contact with the bottom electrode 102 and the insulator IL. According to an exemplary embodiment, likewise, the non-magnetic amorphous insertion layer 103 comprises a bottom layer 103a, a middle layer 103b, and a top layer 103c. According to an exemplary embodiment, the bottom layer 103a is an amorphous magnetic film, the middle layer 103b is a non-magnetic conductive film, and the top layer 103c is a non-magnetic metal film. According to an exemplary embodiment, similar to the tri-layered structure of the non-magnetic amorphous insertion layer 103 as depicted in FIG. 3, a multiple repeats of the tri-layer in the form of [103a/103b/103c]n can be formed, where n is a number of repeats.

According to an exemplary embodiment, the amorphous magnetic film of the bottom layer 103a may have a thickness of 2-10 angstroms and a composition of (CoₓFe₁₀₀₋ₓ)_{y}B_{100-y}, wherein 0≤x≤100 and 20≤y≤80, which can provide small film stress, smooth surface, and negligible magnetic property when its thickness is less than 5 angstroms. According to some embodiments, the amorphous magnetic film of the bottom layer 103a may comprise non-stoichiometric CoFeB, TbFe, TbCo, GdCo, CoFeBTa, CoFeBW, CoFeBMo, CoSiBZr, CoFeBTi, CoFeBHc, CoFeBNb, or CoFeSi, which comprises glass-forming elements such as B, Si, Tb, or Gd, and can be deposited by physical vapor deposition (PVD) techniques. The crystallization temperatures of the amorphous magnetic film of the bottom layer 103a can be controlled by adjusting the composition and therefore no concern of thermal stability.

According to an exemplary embodiment, the non-magnetic conductive layer of the middle layer 103b may comprise conductive oxide or nitride layer including, but not limited to, non-stoichiometric MgO, LaNiOx, TiOx, MgZnOx, TaN, or TiN with thickness from 0.1-5 angstroms. Atomic inter-diffusion of boron during the subsequent annealing process may degrade the performance of the MTJs. The non-magnetic conductive oxide/nitride film may function as a diffusion barrier that prevents the inter-diffusion of the boron atoms derived from the CoFeB bottom layer 103a.

According to an exemplary embodiment, the non-magnetic metal film of the top layer 103c may comprise Ta, W, Mo, Zr, Ti, Hf, Nb, or a combination thereof, with a thickness of 0.1-10 angstroms. The high chemical affinity of non-magnetic metal layer can further prevent boron diffusion.

According to some embodiments, the bottom layer 103a may comprise non-magnetic metal film comprising Ta, W, Mo, Zr, Ti, Hf, Nb, or a combination thereof, with a thickness of 0.1-10 angstroms, the middle layer 103b is a non-magnetic conductive film, and the top layer 103c may have a composition of (CoₓFe₁₀₀₋ₓ)_{y}B_{100-y}, wherein 0≤x≤100 and 20≤y≤80. According to some embodiments, the non-magnetic amorphous insertion layer 103 can have a repeating layer structure of [non-magnetic metal layer/non-magnetic conductive layer/amorphous magnetic layer]n, wherein n is an integral between 1-5, inclusive.

The non-magnetic amorphous insertion layer 103 can prevent crystallinity of the bottom electrode 102 and the metal layer 101 from disturbing the texture seeding of the seed layer 10. In addition, the non-magnetic amorphous insertion layer 103 can prevent impurity derived from the bottom electrode 102 and the metal layer 101 from inter-diffusing into the seed layer 104 after chemical mechanical polishing (CMP). The radial resistance-area products (RA)/tunnel magnetoresistance (TMR) uniformity on 300 mm wafer can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor memory device, comprising:
a bottom electrode;
a magnetic tunnel junction (MTJ) structure disposed over the bottom electrode;
a seed layer disposed between the MTJ structure and the bottom electrode; and
a non-magnetic amorphous insertion layer disposed between the seed layer and the bottom electrode.

2. The semiconductor memory device according to claim 1, wherein the seed layer comprises Pt, Co, Ru, Ir or a combination thereof.

3. The semiconductor memory device according to claim 1, wherein the non-magnetic amorphous insertion layer comprises a bottom layer directly disposed on the bottom electrode, a middle layer directly disposed on the bottom layer, and a top layer directly disposed on the middle layer, wherein the bottom layer, the middle layer, and the top layer have different compositions, and wherein the non-magnetic amorphous insertion layer further comprises a multilayer structure of bottom layer/middle layer/top layer as a form of [bottom layer/middle layer/top layer]n, where n is a number of repeats.

4. The semiconductor memory device according to claim 3, wherein the bottom layer is an amorphous magnetic film, the middle layer is a non-magnetic conductive film, and the top layer is a non-magnetic metal film.

5. The semiconductor memory device according to claim 4, wherein the amorphous magnetic film comprises (CoₓFe₁₀₀₋ₓ)_{y}B_{100-y}, wherein 0≤x≤100 and 20≤y≤80.

6. The semiconductor memory device according to claim 4, wherein the amorphous magnetic film has a thickness of 2-10 angstroms.

7. The semiconductor memory device according to claim 4, wherein the amorphous magnetic film comprises CoFeB, TbFe, TbCo, GdCo, CoFeBTa, CoFeBW, CoFeBMo, CoSiBZr, CoFeBTi, CoFeBHc, CoFeBNb, or CoFeSi.

8. The semiconductor memory device according to claim 4, wherein the non-magnetic conductive layer comprises MgO, LaNiOx, TiOx, MgZnOx, TaN, or TiN.

9. The semiconductor memory device according to claim 4, wherein the non-magnetic conductive layer has a thickness of 0.1-5 angstroms.

10. The semiconductor memory device according to claim 4, wherein the non-magnetic metal film comprises Ta, W, Mo, Zr, Ti, Hf, Nb, or a combination thereof.

11. The semiconductor memory device according to claim 4, wherein the non-magnetic metal film has a thickness of 0.1-10 angstroms.

12. The semiconductor memory device according to claim 3, wherein the bottom layer is a non-magnetic metal film, the middle layer is a non-magnetic conductive film, and the top layer is an amorphous magnetic film.

13. The semiconductor memory device according to claim 12, wherein the non-magnetic metal film comprises Ta, W, Mo, Zr, Ti, Hf, Nb, or a combination thereof.

14. The semiconductor memory device according to claim 12, wherein the non-magnetic conductive layer comprises MgO, LaNiOx, TiOx, MgZnOx, TaN, or TiN.

15. The semiconductor memory device according to claim 12, wherein the amorphous magnetic film comprises (CoₓFe₁₀₀₋ₓ)_{y}B_{100-y}, wherein 0≤x≤100 and 20≤y≤80.

16. The semiconductor memory device according to claim 12, wherein the amorphous magnetic film has a thickness of 2-10 angstroms.

17. The semiconductor memory device according to claim 12, wherein the amorphous magnetic film comprises CoFeB, TbFe, TbCo, GdCo, CoFeBTa, CoFeBW, CoFeBMo, CoSiBZr, CoFeBTi, CoFeBHc, CoFeBNb, or CoFeSi.

18. The semiconductor memory device according to claim 1 further comprising:
an insulator surrounding the bottom electrode, wherein the non-magnetic amorphous insertion layer is in direct contact with the bottom electrode and the insulator.

19. The semiconductor memory device according to claim 18, wherein the bottom electrode has a first width and the MTJ structure has a second width, wherein the second width is greater than the first width.

20. The semiconductor memory device according to claim 18, wherein the insulator comprises silicon oxide.
